(19) United States
(12) Patent Application Publication
(10) Pub. No.: US 2025/0251456 A1
(43) Pub. Date: Aug. 7, 2025

(54) INFORMATION PROCESSING METHOD AND INFORMATION PROCESSING SYSTEM FOR BATTERY, AND NON-TRANSITORY STORAGE MEDIUM

(71) Applicant: KABUSHIKI KAISHA TOSHIBA, Tokyo (JP)

(72) Inventors: Sayaka MORIMOTO, Kawasaki Kanagawa (JP); Ryosuke YAGI, Yokohama Kanagawa (JP)

(73) Assignee: KABUSHIKI KAISHA TOSHIBA, Tokyo (JP)

(21) Appl. No.: 19/036,142

(22) Filed: Jan. 24, 2025

(30) Foreign Application Priority Data
Feb. 1, 2024 (JP) 2024-014355

(51) Int. Cl. G01R 31/3842; G01R 31/392

(52) U.S. Cl. CPC G01R 31/3842; G01R 31/392

(57) ABSTRACT

In embodiments, an information processing method for a battery includes: calculating, based on operation plan information indicating an operation plan of either the battery or a battery-mounted apparatus in which the battery is mounted, time-series data indicating a time change in each of a current, a voltage, and a temperature of the battery of a case where the battery is operated in accordance with the operation plan in the operation plan information. In the information processing method, a degradation state of the battery of the case where the battery is operated in accordance with the operation plan is calculated using the calculated time-series data.

### CROSS-REFERENCE TO RELATED APPLICATION

This application is based upon and claims the benefit of priority from Japanese Patent Application No. 2024-014355, filed Feb. 1, 2024; the entire contents of which are incorporated herein by reference.

### FIELD

Embodiments described herein relate generally to an information processing method and an information processing system for battery, and a storage medium.

### BACKGROUND

In a case of estimating a degradation state of a battery, measurement data indicating a time change in each of a current, a voltage, and a temperature of the battery is measured in a state where the battery is operated. Then, a state change of the battery including a change in battery capacity and a change in resistance of the battery is calculated based on the measurement data, and the degradation state of the battery is estimated.

In a case where a battery is mounted on a battery-mounted apparatus and operated, it is required to enable estimation of the degradation state of the battery of a case where the battery is operated in accordance with an operation plan at a stage before the battery is operated, such as a stage of the operation plan. For example, at the stage before the battery is operated, it is required to enable estimation of the degradation state of the battery at a time point when the operation of the battery in accordance with to the operation plan has been performed for a predetermined period.

### BRIEF DESCRIPTION OF DRAWINGS

FIG. 1 is a block diagram schematically illustrating an information processing system according to a first embodiment.

FIG. 2 is a flowchart schematically illustrating an example of processing performed by the information processing system according to the first embodiment.

FIG. 3 is a schematic diagram illustrating an example of time-series data calculated using operation plan information and an electrochemical model in the first embodiment.

FIG. 4 is a flowchart schematically illustrating an example of processing of calculating a degradation state of a battery in an operation in accordance with an operation plan, which is performed in the first embodiment.

FIG. 5 is a schematic diagram illustrating an example of processing of calculating an operation condition parameter for each of a plurality of time frames, which is performed in the first embodiment.

FIG. 6 is a schematic diagram illustrating an example of relational data of a degradation prediction model used for processing of calculating a state change speed in each of the plurality of time frames in the first embodiment.

FIG. 7 is a flowchart schematically illustrating an example of processing performed by an information processing system according to a second embodiment.

FIG. 8 is a flowchart schematically illustrating an example of processing of calculating an operation condition of a battery that satisfies a user's request, which is performed in the second embodiment.

FIG. 9 is a flowchart schematically illustrating an example of processing performed by an information processing system according to a third embodiment.

FIG. 10 is a block diagram schematically illustrating an information processing system according to a modification.

### DETAILED DESCRIPTION

In embodiments, an information processing method for a battery includes: calculating, based on operation plan information indicating an operation plan of either the battery or a battery-mounted apparatus in which the battery is mounted, time-series data indicating a time change in each of a current, a voltage, and a temperature of the battery of a case where the battery is operated in accordance with the operation plan in the operation plan information. In the information processing method, a degradation state of the battery of the case where the battery is operated in accordance with the operation plan is calculated using the calculated time-series data.

Hereinafter, embodiments will be described with reference to the drawings.

### First Embodiment

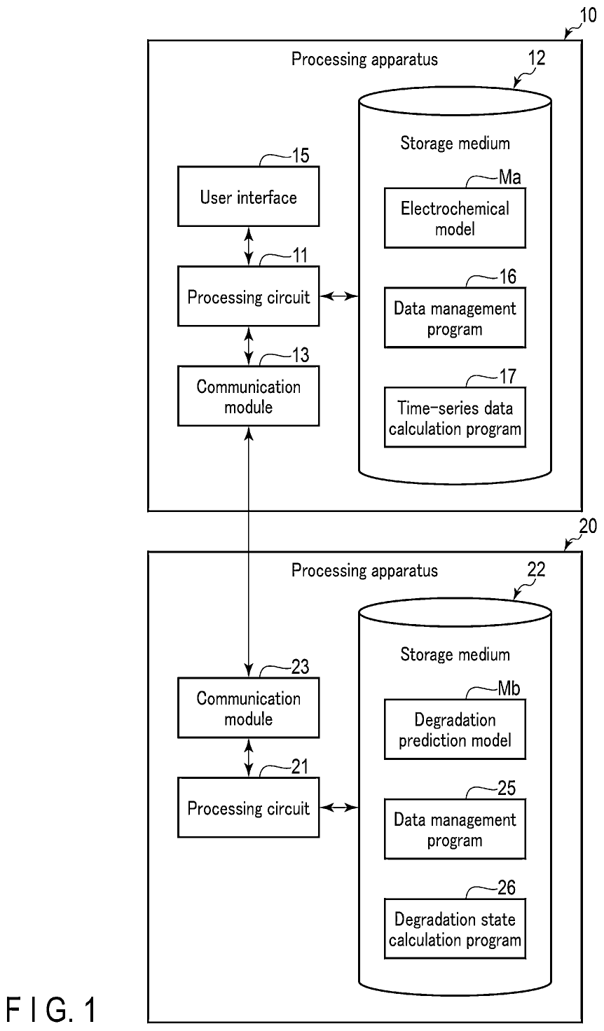

First, a first embodiment will be described as an example of an embodiment. FIG. 1 is a block diagram schematically illustrating an information processing system 1 according to the first embodiment. In the information processing system 1, information processing is performed for a battery, and for example, information processing is performed for a battery mounted on a battery-mounted apparatus. Examples of the battery-mounted apparatus in which the battery is mounted include a vehicle, a large power storage apparatus for an electric power system, a smartphone, a stationary power supply apparatus, a robot, a drone, and the like. Further, examples of the vehicle serving as the battery-mounted apparatus include a railway vehicle, an electric bus, an electric vehicle, a plug-in hybrid vehicle, and an electric motorcycle. In the present embodiment, the information processing system 1 is used at a stage before operating the battery, such as a stage of an operation plan of the battery and the battery-mounted apparatus.

Further, the battery to be operated, that is, the battery to be mounted on the battery-mounted apparatus is, for example, a secondary battery such as a lithium ion secondary battery. The battery to be operated may be formed of a unit cell (unit battery), or may be a battery module or a cell block formed by electrically connecting a plurality of the unit cells. In the case where the battery is formed of a plurality of unit cells, the plurality of unit cells may be electrically connected in series or the plurality of unit cells may be electrically connected in parallel in the battery. Further, both a series connection structure in which the plurality of unit cells is connected in series and a parallel connection structure in which the plurality of unit cells is connected in parallel may be formed in the battery. Further, the battery to be operated may be any of a battery string, a battery array, or a storage battery, in which a plurality of the battery modules is electrically connected. Further, in a case where the battery module in which the plurality of unit cells is electrically connected is used as the battery to be operated, processing to be described below using the information processing system 1 may be performed for each of the plurality of unit cells constituting the battery module.

Further, the batteries such as the secondary batteries are classified into a plurality of types of batteries based on a composition of a positive electrode, a composition of a negative electrode, a composition of an electrolyte, and the like. Each of the plurality of types of batteries is different from the other types of batteries in any one or more of the composition of the positive electrode, the composition of the negative electrode, and the composition of the electrolyte. The composition of each of the positive electrode and the negative electrode includes a type of an active material, a content percentage of the active material in an active material-containing layer, and the like. The composition of the electrolyte includes a type of the electrolyte, a concentration of the electrolyte in an electrolytic solution, and the like. Note that, in the present embodiment, the processing to be described below will be described on the premise that the battery to be operated is determined to be an arbitrary type.

The information processing system 1 in the example of FIG. 1 includes two processing apparatuses 10 and 20. The processing apparatus (first processing apparatus) 10 is a computer, and includes, for example, any of a server, a personal computer, a terminal, or the like. The processing apparatus 10 is managed by, for example, a user who uses a service using the information processing system 1. The processing apparatus 10 includes a processing circuit (first processing circuit) 11, a storage medium (non-transitory storage medium) 12, a communication module 13, and a user interface 15. The processing circuit 11 includes a processor, an integrated circuit, or the like, and the processor or the like constituting the processing circuit 11 includes any of a central processing unit (CPU), an application specific integrated circuit (ASIC), a microcomputer, a field programmable gate array (FPGA), a digital signal processor (DSP), or the like. The processing circuit 11 may include one processor or the like, or may include a plurality of the processors or the like.

The storage medium 12 is either a main storage apparatus such as a memory or an auxiliary storage apparatus. Examples of the storage medium 12 include a magnetic disk, an optical disk (CD-ROM, CD-R, DVD, or the like), a magneto-optical disk (MO or the like), a semiconductor memory, and the like. In the processing apparatus 10, only one memory or the like serving as the storage medium 12 may be provided, or a plurality of memories or the like may be provided.

The processing circuit 11 performs processing by executing a program or the like stored in the storage medium 12. In the example of FIG. 1, the program executed by the processing circuit 11 includes a data management program 16 and a time-series data calculation program 17. The processing circuit 11 executes the data management program 16 to write data to the storage medium 12 and read data from the storage medium 12. Furthermore, the time-series data calculation program 17 constitutes a part of an information processing program that causes the information processing system 1 to execute processing to be described below.

In one example, the processing circuit 11 of the processing apparatus 10 downloads the time-series data calculation program 17 by downloading a dedicated application via a network, and stores the downloaded time-series data calculation program 17 in the storage medium 12. Further, in the example of FIG. 1, an electrochemical model Ma is stored in the storage medium 12, and the electrochemical model Ma is used in processing based on the time-series data calculation program 17. For example, the processing circuit 11 of the processing apparatus 10 downloads the electrochemical model Ma together with the time-series data calculation program 17, and stores the downloaded electrochemical model Ma in the storage medium 12.

The communication module 13 includes a communication interface of the processing apparatus 10 and the like. The processing circuit 11 communicates with an external apparatus or the like including the processing apparatus 20 via the communication module 13. The communication of the processing apparatus 10 via the communication module 13 is performed in a wired or wireless manner. In the user interface 15, the user of the information processing system 1 or the like inputs an appropriate operation related to the battery to be operated. Therefore, in the user interface 15, any of a button, a mouse, a touch panel, a keyboard, or the like is provided as an operation unit to which the operation is input by the user or the like. Furthermore, the user interface 15 is provided with a notification unit that notifies information related to the battery to be operated. The notification unit notifies information by any of screen display, transmission of sound, or the like. Note that the user interface 15 may be provided separately from the processing apparatus 10.

The processing apparatus (second processing apparatus) 20 is a computer, and includes, for example, a server or the like separate from the processing apparatus 10. The processing apparatus 20 is managed by, for example, a provider of the service using the information processing system 1. The processing apparatus 20 includes a processing circuit (second processing circuit) 21, a storage medium (non-transitory storage medium) 22, and a communication module 23. The processing circuit 21 includes a processor, an integrated circuit, or the like, and the processor or the like constituting the processing circuit 21 includes any of a CPU, an ASIC, a microcomputer, an FPGA, a DSP, or the like. The processing circuit 21 may include one processor or the like, or may include a plurality of the processors or the like.

The storage medium 22 is either a main storage apparatus such as a memory or an auxiliary storage apparatus. Examples of the storage medium 22 include a magnetic disk, an optical disk, a magneto-optical disk, a semiconductor memory, and the like. In the processing apparatus 20, only one memory or the like serving as the storage medium 22 may be provided, or a plurality of memories or the like may be provided.

The processing circuit 21 performs processing by executing a program or the like stored in the storage medium 22. In the example of FIG. 1, the program executed by the processing circuit 21 includes a data management program 25 and a degradation state calculation program 26. The processing circuit 21 executes the data management program 25 to write data to the storage medium 22 and read data from the storage medium 22. Further, the degradation state calculation program 26 constitutes a part of the information processing program for causing the information processing system 1 to execute processing to be described below. In the example of FIG. 1, a degradation prediction model Mb is stored in the storage medium 22, and the degradation prediction model Mb is used in processing based on the degradation state calculation program 26.

The communication module 23 includes a communication interface of the processing apparatus 20 and the like. The processing circuit 21 communicates with an external apparatus or the like including the processing apparatus 10 via the communication module 23. The communication of the processing apparatus 20 via the communication module 23 is performed in a wired or wireless manner.

Note that, in one example, processors or the like of a plurality of processing apparatuses (computers) such as a plurality of servers cooperate to perform the processing based on the degradation state calculation program 26. Furthermore, in another example, the information processing system 1 is provided with a cloud server in a cloud environment instead of the processing apparatus 20. An infrastructure of the cloud environment includes a virtual processor such as a virtual CPU and a cloud memory. In this case, the virtual processor performs the processing to be described below based on the degradation state calculation program 26 instead of the processing circuit 21. Then, similarly to the storage medium 22, the cloud memory functions as a storage area for storing programs, data, and the like.

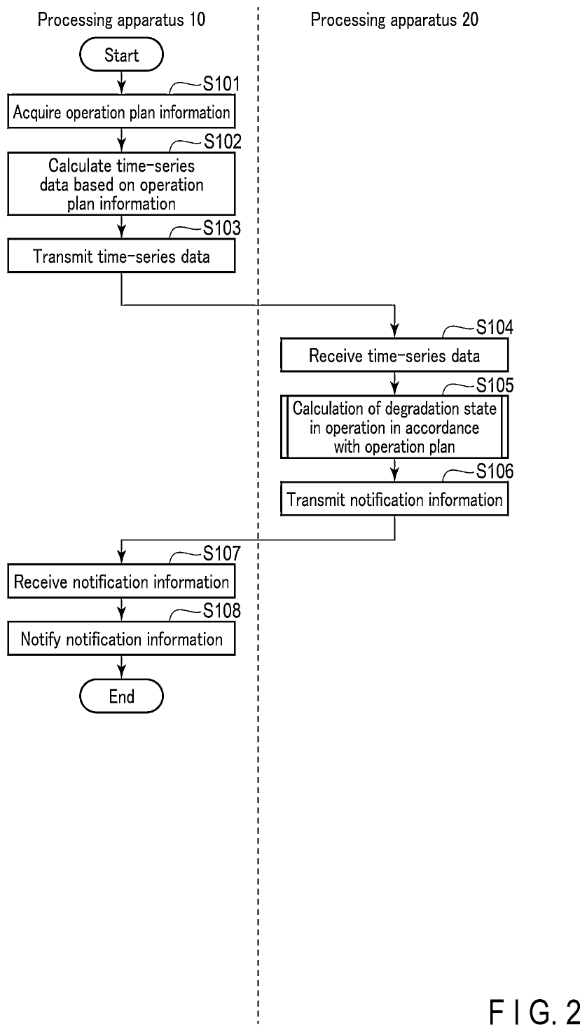

FIG. 2 is a flowchart schematically illustrating an example of the processing performed by the information processing system 1 according to the first embodiment. The processing of the example of FIG. 2 is mainly performed by the processing circuit 11 of the processing apparatus 10 and the processing circuit 21 of the processing apparatus 20, and is performed by the processing apparatuses 10 and 20 or the like executing the information processing program including the time-series data calculation program 17 and the degradation state calculation program 26.

When the processing of the example of FIG. 2 is started, the processing circuit 11 of the processing apparatus 10 acquires operation plan information (S101). The operation plan information is input by the user or the like in the user interface 15. In one example, the processing circuit 11 downloads a dedicated application including the time-series data calculation program 17 and the electrochemical model Ma, thereby forming an environment in which the operation plan information can be input in the user interface 15. The operation plan information indicates an operation plan of either the battery or the battery-mounted apparatus in which the battery is mounted.

The operation plan information includes information regarding power consumption in the battery-mounted apparatus and a charging condition in charging the battery-mounted apparatus. As the information regarding power consumption in the battery-mounted apparatus, for example, a time zone and a time length in which the battery-mounted apparatus consumes power, power consumption and an environmental temperature in a period in which the battery-mounted apparatus consumes the power, and the like are indicated. Further, in a case where the battery-mounted apparatus in which the battery is to be mounted is a vehicle, a time zone and a time length in which the vehicle travels, and a traveling pattern and an environmental temperature in a period in which the vehicle travels are indicated as the information regarding power consumption in the battery-mounted apparatus, instead of or in addition to the above-described information. The traveling pattern of the vehicle includes a traveling route of the vehicle and the like.

As the charging condition in charging of the battery-mounted apparatus, for example, a time zone and a time length in which the battery-mounted apparatus is charged, and charging power, an environmental temperature, and the like in a period in which the battery is charged are indicated. In addition, specification information of a charger to be used and the like may be indicated as the charging condition in charging the battery-mounted apparatus, instead of or in addition to the charging power in the period in which the battery-mounted apparatus is charged.

Further, the operation plan information includes information regarding stop of the charging and discharging of the battery. As the information regarding stop of the charging and discharging of the battery, for example, a time zone and a time length in which the charging and discharging of the battery are stopped, an environmental temperature in a period in which the charging and discharging of the battery are stopped, and the like are indicated. Further, in a case where the battery-mounted apparatus in which the battery is to be mounted is a vehicle, a time zone and a time length in which the vehicle is parked, an environmental temperature during a period in which the vehicle is parked, and the like may be indicated as the information regarding stop of the charging and discharging of the battery, instead of or in addition to the above-described information.

Further, in a case of operation in which power can be output (dischargeable) from the battery-mounted apparatus to an outside, information regarding the output of power from the battery-mounted apparatus is included in the operation plan information. As the information regarding the output of power from the battery-mounted apparatus, for example, a time zone and a time length in which the battery-mounted apparatus outputs the power, output power and an environmental temperature in a period in which the battery-mounted apparatus outputs the power, and the like are indicated.

In the processing of the example of FIG. 2, the processing circuit 11 calculates time-series data based on the operation plan information using the electrochemical model Ma (S102). The processing circuit 11 executes the time-series data calculation program 17 to calculate the time-series data based on the operation plan information. In the electrochemical model Ma, the time-series data is output by inputting the operation plan information. In the processing based on the time-series data calculation program 17, the processing circuit 11 calculates an output result from the electrochemical model Ma as the time-series data by inputting the operation plan information to the electrochemical model Ma.

In the time-series data calculated based on the operation plan information, a time change in each of a current, a voltage, and a temperature of the battery of the case where the battery is operated in accordance with the operation plan in the operation plan information is indicated. In the calculation of the time-series data, the processing circuit 11 calculates each of the current, the voltage, and the temperature of the battery at each of a plurality of time points in a time range indicated by the time-series data, using the operation plan information and the electrochemical model Ma. Thereby, the time change in each of the current, the voltage, and the temperature of the battery of the case where the battery is operated in accordance with the operation plan in the operation plan information is calculated.

In the calculation of the time change in the current of the battery, an arithmetic operation is performed assuming that the current is output from the battery, that is, a discharging current flows through the battery, in the period in which the battery-mounted apparatus consumes the power and the period in which the battery-mounted apparatus outputs the power. At this time, an absolute value (magnitude) of the discharging current (output current) from the battery is calculated to be a larger value as the power consumption in the battery-mounted apparatus is larger. Then, the absolute value of the discharging current from the battery is calculated to be a larger value as the output power from the battery-mounted apparatus is larger.

In a case where the operation plan information indicates the traveling pattern or the like of the vehicle instead of the power consumption in the battery-mounted apparatus, the power consumption in the period in which the vehicle as the battery-mounted apparatus travels is calculated based on the traveling pattern including the traveling route in the calculation of the time change in the current of the battery. Then, the discharging current from the battery is calculated based on the calculated power consumption in the vehicle. In this case, for example, in a period in which the vehicle travels on an uphill, the power consumption in the vehicle is calculated to be a larger value than a period in which the vehicle travels on a flat road, and the absolute value (magnitude) of the discharging current (output current) from the battery is calculated to be a large value. Further, in a period in which the vehicle travels on a downhill, the power consumption in the vehicle is calculated to be a smaller value than a period in which the vehicle travels on a flat road, and the absolute value of the discharging current from the battery is calculated to be a small value.

Further, in the calculation of the time change in the current of the battery, the arithmetic operation is performed assuming that the current is input to the battery, that is, the charging current flows through the battery, in the period in which the battery-mounted apparatus is charged. At this time, the absolute value (magnitude) of the charging current (input current) to the battery is calculated to be a larger value as the charging power indicated by the charging condition or the like is larger. In addition, in a case where the specification information of the charger and the like is indicated in the charging condition in the operation plan information instead of the charging power, the charging power in the period in which the battery-mounted apparatus is charged is calculated based on the specification information of the charger. Further, in the calculation of the time change in the current of the battery, the arithmetic operation is performed assuming that no current flows through the battery, that is, the current value of the battery is zero, in the period in which the charging and discharging of the battery are stopped. By performing the arithmetic operation as described above, the time change in the current of the battery of the case where the battery is operated in accordance with the operation plan is calculated based on the operation plan information.

The time change in the voltage of the battery is calculated using a calculation result of the time change in the current after calculating the time change in the current of the battery as described above, for example. Then, in the calculation of the time change in the voltage of the battery, the arithmetic operation is performed assuming that the voltage of the battery decreases over time during the period in which the current is output from the battery, that is, the period of discharging from the battery. At this time, a time decreasing rate of the voltage is calculated to be a larger value as the absolute value of the discharging current is larger. Further, a decrease amount in voltage during the discharging period is calculated to be a larger value as the time length of discharging is longer.

Further, in the calculation of the time change in the voltage of the battery, the arithmetic operation is performed assuming that the voltage of the battery increases over time during the period of inputting the current to the battery, that is, the period of charging the battery. At this time, a time increasing rate of the voltage is calculated to be a larger value as the absolute value of the charging current is larger. Further, an increase amount in voltage during the charging period is calculated to be a larger value as the time length of charging is longer. Further, in the calculation of the time change in the voltage of the battery, the arithmetic operation is performed assuming that no voltage of the battery is changed in the period in which the charging and discharging of the battery are stopped. By performing the arithmetic operation as described above, the time change in the voltage of the battery of the case where the battery is operated in accordance with the operation plan is calculated based on the operation plan information.

Further, the time change in the temperature of the battery is calculated by, for example, calculating the time change in the current of the battery as described above, and then using the calculation result of the time change in the current, the environmental temperature at each of the plurality of time points indicated by the operation plan information, and the like. In the calculation of the time change in the temperature of the battery, the temperature of the battery is calculated to be a higher value as the environmental temperature is higher if other conditions are the same. Note that, in the calculation of the time change in the temperature of the battery, the arithmetic operation is performed in consideration of an influence of heat caused by the current (discharging current and charging current) flowing through the battery in addition to the environmental temperature. Therefore, even if the environmental temperature is the same, the temperature of the battery is calculated to be a higher value at a time point when the current has been continuously flowing through the battery for a certain period of time or the like than at a time point when the charging and discharging of the battery have been stopped for a certain period of time or the like. By performing the arithmetic operation as described above, the time change in the temperature of the battery of the case where the battery is operated in accordance with the operation plan is calculated based on the operation plan information.

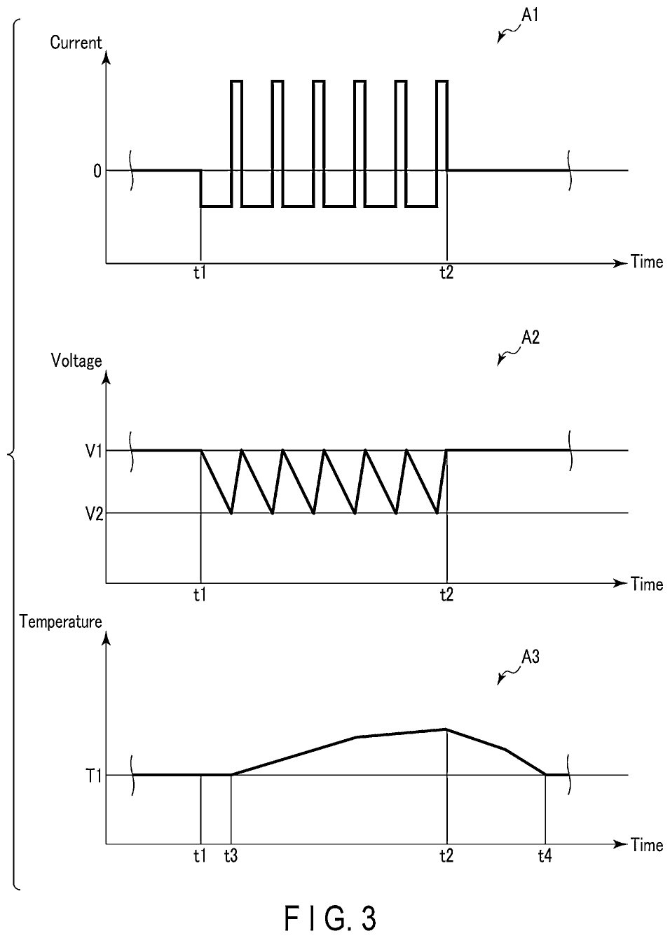

FIG. 3 schematically illustrates an example of the time-series data calculated using the operation plan information and the electrochemical model Ma in the first embodiment. In the example of FIG. 3, graphs A1, A2, and A3 are calculated as the time-series data. The graph A1 shows the time change in the current of the battery of the case where the battery is operated in accordance with the operation plan, the graph A2 shows the time change in the voltage of the battery of the case where the battery is operated in accordance with the operation plan, and the graph A3 shows the time change in the temperature of the battery of the case where the battery is operated in accordance with the operation plan. In each of the graphs A1 to A3, the abscissa axis represents time. In the graph A1, the ordinate axis represents the current, in the graph A2, the ordinate axis represents the voltage, and in the graph A3, the ordinate axis represents the temperature. In the graph A1, the current input to the battery, that is, the charging current of the battery is indicated by a positive value, and the current output from the battery, that is, the discharging current is indicated by a negative value.

In the time-series data calculated in the example of FIG. 3, the charging and discharging of the battery are stopped from a certain time point (not illustrated) before a time t1, and the voltage of the battery is maintained at a voltage value V1. Then, at the time t1, the discharging from the battery is started, and between the time t1 and a time t2 after the time t1, either the charging or the discharging of the battery is performed, and the current continuously flows through the battery. Between the time t1 and the time t2, the discharging of the battery from the voltage value V1 to a voltage value V2 lower than the voltage value V1, and the charging of the battery from the voltage value V2 to the voltage value V1 are alternately repeated. Then, at the time t2, the state is switched to the state in which the charging and discharging of the battery are stopped, and the voltage of the battery is maintained at the voltage value V1 from the time t2 to a certain time point (not illustrated) after the time t2.

Further, in the time-series data calculated in the example of FIG. 3, the temperature of the battery is maintained at a temperature T1 from a certain time point (not illustrated) before the time t1. When the discharging from the battery is started at the time t1, the temperature of the battery increases from the temperature T1 at a time t3 between the time t1 and the time t2. Then, even if the charging and discharging of the battery are stopped at the time t2, the temperature of the battery is maintained in a state higher than the temperature T1. Then, at a time t4 after the time t2, the temperature of the battery decreases to the temperature T1, and from the time t4 to a certain time point (not illustrated) after the time t4, the temperature of the battery is maintained at the temperature T1.

In the processing of the example of FIG. 2, the processing circuit 11 of the processing apparatus 10 transmits the time-series data calculated as described above to the processing apparatus 20 via the communication module 13 (S103). Then, the processing circuit 21 of the processing apparatus 20 receives the time-series data from the processing apparatus 10 via the communication module 23 (S104). Then, the processing circuit 21 calculates a degradation state of the battery of the case where the battery is operated in accordance with the operation plan in the operation plan information, using the time-series data received from the processing apparatus 10 (S105). The processing circuit 21 executes the degradation state calculation program 26 to calculate the degradation state of the battery of the case where the battery is operated in accordance with the operation plan.

The processing circuit 21 calculates the degradation state of the battery at the time point when the operation of the battery in accordance with the operation plan has been performed for a predetermined period. In one example, in the operation in accordance with the operation plan, when the voltage of the battery decreases to some extent due to the discharging from the battery, the battery is charged. Then, the processing circuit 21 calculates the degradation state of the battery at the time point when the 10000th charging of the battery has been performed since the time point of starting the operation. Further, in one example, in the calculation of the degradation state of the battery, any one or more of a capacity retention rate of a battery capacity with respect to the time point of starting the operation and a resistance increase rate of a resistance of the battery with respect to the time point of starting the operation is calculated as an index indicating the degradation state of the battery.

Here, in the battery, a lower limit voltage and an upper limit voltage are defined for the voltage. In the battery, a charging capacity (charging charge amount) from the lower limit voltage to the upper limit voltage in charging under a predetermined charging condition, or a discharging capacity (discharging charge amount) from the upper limit voltage to the lower limit voltage in discharging under a predetermined discharging condition is defined as the battery capacity. The battery capacity of the battery decreases as the degree of degradation of the battery increases. Therefore, it is possible to determine the degradation state of the battery based on the battery capacity retention rate with respect to the time point of starting the operation. In addition, the resistance of the battery increases as the degree of degradation of the battery increases. Therefore, it is possible to determine the degradation state of the battery based on the resistance increase rate with respect to the starting time point of the operation.

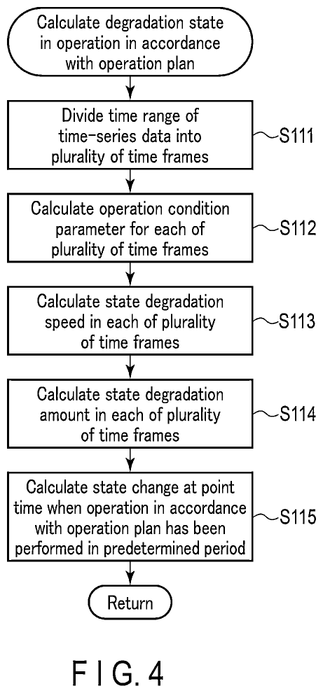

FIG. 4 is a flowchart schematically illustrating an example of processing of calculating a degradation state of a battery in an operation in accordance with an operation plan, that is, the processing of S105 of FIG. 2, which is performed in the first embodiment. In the example of FIG. 4, in the calculation of the degradation state of the battery, the processing circuit 21 of the processing apparatus 20 divides the time range indicated by the time-series data into a plurality of time frames (S111). By performing such processing, in one example, a time domain in which either the charging or discharging of the battery is performed is divided into a plurality of time frames, and a time domain in which the charging and discharging of the battery are stopped is divided into a plurality of time frames in the time-series data.

Then, the processing circuit 21 calculates an operation condition parameter indicating the operation condition of the battery based on the time-series data for each of the plurality of divided time frames (S112). At this time, one or more operation condition parameters are calculated for each of the plurality of time frames of the time-series data.

In one example, a maximum SOC value of the battery, a minimum SOC value of the battery, an average temperature of the battery, and an average current value of the battery are calculated as the operation condition parameters for each of the time frames included in the time domain in which either the charging or discharging of the battery is performed among the plurality of time frames based on the time-series data. Then, a maintained SOC value of the battery and the average temperature of the battery are calculated as the operation condition parameters for each of the time frames included in the time domain in which the charging and discharging of the battery are stopped among the plurality of time frames based on the time-series data. In the case of calculating the operation condition parameters for each of the plurality of time frames as in the present example, the processing circuit 21 calculates the time change in the state of charge (SOC) value of the battery of the case where the battery is operated in accordance with the operation plan based on the time-series data.

Here, in the battery, a state in which the SOC value is 0% and a state in which the SOC value is 100% where the charge amount (charging amount) of the battery is larger than that in the state in which the SOC value is 0% are defined. Then, a ratio of a remaining charge amount to the state where the SOC value is 0% to a total charge amount between the state in which the SOC value is 0% and the state in which the SOC value is 100% is defined as the SOC value. During the period of charging of the battery, the SOC value of the battery increases over time, and during the period of discharging from the battery, the SOC value of the battery decreases over time. Further, during the period in which the charging and discharging of the battery are stopped, the SOC value of the battery is maintained without being changed.

In one example, a time change in an open-circuit voltage of the battery of the case where the battery is operated in accordance with the operation plan is calculated based on the time change in the current, the voltage, and the temperature of the battery indicated by the time-series data. Then, relational data indicating a relationship between the open-circuit voltage of the battery and the SOC value is stored in the storage medium 22 or the like, and the time change in the SOC value of the battery of the case where the battery is operated in accordance with the operation plan is calculated based on the relationship between the open-circuit voltage of the battery and the SOC value indicated by the relational data and a calculation result of the time change in the open-circuit voltage of the battery. In another example, a time change in the charge amount of the battery of the case where the battery is operated in accordance with the operation plan is calculated based on the time change in the current of the battery or the like indicated by the time-series data. At this time, the time change in the charge amount of the battery is calculated based on a time integrated value of the current or the like. Then, the time change in the SOC value of the battery of the case where the battery is operated in accordance with the operation plan is calculated based on a calculation result of the time change in the charge amount of the battery.

The maximum SOC value and the minimum SOC are calculated for each of the time frames included in the time domain in which either the charging or discharging of the battery is performed based on a calculation result of the time change in the SOC value of the battery. At this time, for each time frame, a maximum value of the SOC value of the battery in the time frame is calculated as the maximum SOC value, and a minimum value of the SOC value of the battery in the time frame is calculated as the minimum SOC value. Further, for each of the time frames included in the time domain in which either the charging or discharging of the battery is performed, an average value of the temperature of the battery in the time frame is calculated as the above-described average temperature based on the time change in the temperature of the battery indicated by the time-series data. Then, for each of the time frames included in the time domain in which either the charging or discharging of the battery is performed, an average value of the absolute values of the current of the battery in the time frame is calculated as the above-described average current value based on the time change in the current of the battery indicated by the time-series data.

For each of the time frames included in the time domain in which the charging and discharging of the battery are stopped, the maintained SOC value is calculated based on a calculation result of the time change in the SOC value of the battery. At this time, for each time frame, the SOC value of the battery maintained in the time frame is calculated as the maintained SOC value. Further, for each of the time frames included in the time domain in which the charging and discharging of the battery are stopped, the average value of the temperature of the battery in the time frame is calculated as the above-described average temperature.

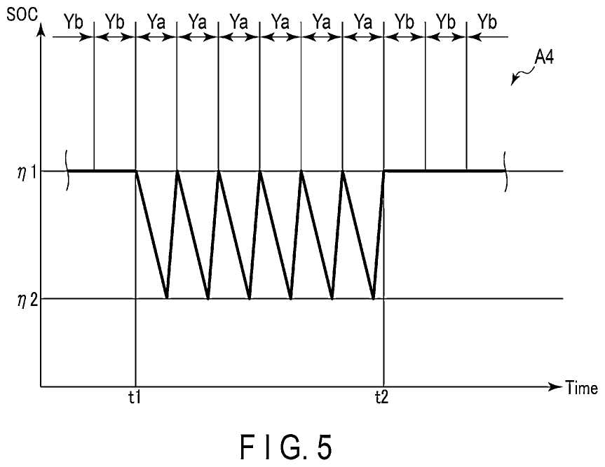

FIG. 5 schematically illustrates an example of processing of calculating the operation condition parameters for each of the plurality of time frames, which is performed in the first embodiment. In the example of FIG. 5, the time change in the SOC value of the battery of the case where the battery is operated in accordance with the operation plan is calculated based on the time-series data of the example of FIG. 3, and the calculated time change in the SOC value is illustrated in graph A4. In the graph A4, the abscissa axis represents the time, and the ordinate axis represents the SOC value.

In the time change in the SOC value calculated in the example of FIG. 5, the battery is maintained at an SOC value η1 from a certain time point (not illustrated) before time t1. Then, between the time t1 and time t2, a decrease over time in the SOC value from the SOC value η1 to an SOC value η2 lower than the SOC value η1 due to the discharging from the battery, and an increase over time in the SOC value from the SOC value η2 to the SOC value η1 due to the charging of the battery are alternately repeated. Then, from the time t2 to a certain time point (not illustrated) after the time t2, the battery is maintained at the SOC value η1.

Further, in the example of FIG. 5, the time domain in which either the charging or discharging of the battery is performed between the time t1 and the time t2 is divided into a plurality of time frames Ya. At this time, one cycle of alternately repeated the charging and discharging is set as one time frame Ya, and the time domain between the time t1 and the time t2 is divided into the plurality of time frames Ya. Further, in the example of FIG. 5, each of the time domain in which the charging and discharging of the battery are stopped where the time t1 is the end time point and the time domain in which the charging and discharging of the battery are stopped where the time t2 is the start time point is divided into a plurality of time frames Yb.

In the example of FIG. 5, the processing circuit 21 or the like calculates the maximum SOC value, the minimum SOC value, the average temperature, and the average current value described above as the operation condition parameters for each of the time frames Ya, and calculates the maintained SOC value and the average temperature described above as the operation condition parameters for each of the time frames Yb. At this time, for each of the time frames Ya, the SOC value η1 is calculated as the maximum SOC value, and the SOC value η2 is calculated as the minimum SOC value. Further, for each of the time frames Yb, the SOC value η1 is calculated as the maintained SOC value.

In the processing of the example of FIG. 4, the processing circuit 21 calculates a state change speed in each of the plurality of time frames based on the calculated operation condition parameters (S113). The degradation prediction model Mb is used in the calculation of the state change speed in each time frame. In the degradation prediction model Mb, the state change speed of the battery is output by inputting the operation condition parameters for the battery. The processing circuit 21 calculates an output result from the degradation prediction model Mb as the state change speed of the battery by inputting the calculated operation condition parameters to the degradation prediction model Mb for each of the plurality of time frames. In one example, as the state change speed of the battery, one or more of a decreasing speed of the battery capacity and an increasing speed of the resistance of the battery are calculated.

In the calculation of the state change speed of the battery in each of the plurality of time frames, one or more pieces of the relational data included in the degradation prediction model Mb are used. In each piece of the relational data of the degradation prediction model Mb, a relationship of the state change speed of the battery with respect to the operation condition parameter of the battery is indicated, and for example, any one of an arithmetic expression, a function, a graph, a table, or the like for calculating the state change speed of the battery from the operation condition parameter of the battery is indicated.

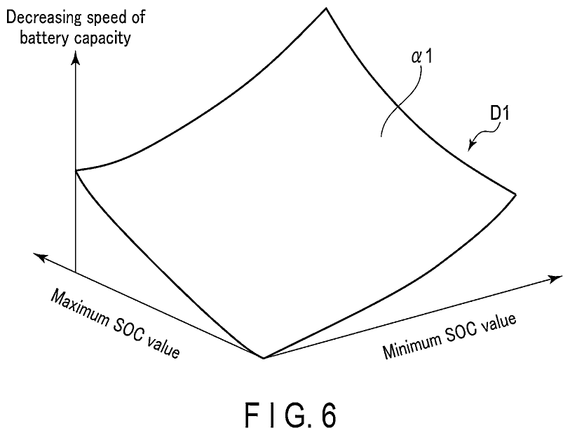

FIG. 6 illustrates an example of the relational data of the degradation prediction model Mb used for the processing of calculating the state change speed in each of the plurality of time frames in the first embodiment. Relational data D1 in the example of FIG. 6 is illustrated by a graph of a triaxial coordinate system, and the three axes represent the maximum SOC value, the minimum SOC value, and the decreasing speed of the battery capacity, respectively. In the relational data D1, the relationship of the decreasing speed of the battery capacity, which is the state change speed of the battery, with respect to the maximum SOC value and the minimum SOC value is illustrated by a response curved surface al. In the degradation prediction model Mb, a response curved surface similar to the response curved surface al of the example of FIG. 6 is illustrated for each of a plurality of conditions in which at least one of the temperature and the absolute value of the current of the battery is different from one another. Therefore, in the degradation prediction model Mb, a function for calculating the decreasing speed of the battery capacity, using the maximum SOC value, the minimum SOC value, the temperature, and the absolute value of the current as arguments is indicated.

In one example, any one of an arithmetic expression, a function, a graph, a table, or the like for calculating the increasing speed of the resistance of the battery, using the maximum SOC value, the minimum SOC value, the temperature, and the absolute value of the current is indicated in the relational data of the degradation prediction model Mb. Since the relational data as described above is included in the degradation prediction model Mb, the state change speed such as the decreasing speed of the battery capacity and the increasing speed of the resistance is calculated based on the relational data of the degradation prediction model Mb and the maximum SOC value, the minimum SOC value, the average temperature, and the average current value calculated as the operation condition parameters, for each of the time frames included in the time domain in which either the charging or discharging of the battery is performed.

Further, in one example, at least one of the relational data indicating the relationship of the decreasing speed of the battery capacity with respect to the maintained SOC value and the temperature and the relational data indicating the relationship of the increasing speed of the resistance with respect to the maintained SOC value and the temperature is included in the degradation prediction model Mb. In this case, for example, in the graph of the triaxial coordinate system, the relationship of the decreasing speed of the battery capacity with respect to the maintained SOC value and the temperature is illustrated by the response curved surface. Since such relational data is included in the degradation prediction model Mb, the state change speeds such as the decreasing speed of the battery capacity and the increasing speed of the resistance are calculated based on the relational data of the degradation prediction model Mb and the maintained SOC value and the average temperature calculated as the operation condition parameters, for each of the time frames included in the time domain in which the charging and discharging of the battery are stopped.

In the processing of the example of FIG. 4, the processing circuit 21 calculates a state change amount of the battery in each of the plurality of time frames based on the calculated state change speed (S114). At this time, for each of the plurality of time frames, the state change amount is calculated by multiplying the calculated state change speed by a time length of the time frame. In one example, the decreasing speed of the battery capacity and the increasing speed of the resistance are calculated as the state change speeds for each of the plurality of time frames. In this case, for each of the plurality of time frames, a decrease amount of the battery capacity in the time frame is calculated as the state change amount of the battery capacity by multiplying the decreasing speed of the battery capacity by the time length. Then, for each of the plurality of time frames, an increase amount of the resistance in the time frame is calculated as the state change amount of the battery by multiplying the increasing speed of the resistance by the time length.

Then, the processing circuit 21 calculates the state change in the battery at the time point when the operation of the battery in accordance with the operation plan has been performed for a predetermined period as the degradation state of the battery based on the calculation result of the state change amount of the battery in each of the plurality of time frames (S115). At this time, as the state change amount at the time point when the operation of the battery in accordance with the operation plan has been performed for a predetermined period, a decrease amount of the battery capacity with respect to the time point of starting the operation and an increase amount of the resistance with respect to the time point of starting the operation are calculated. The state change amount at the time point when the operation of the battery in accordance with the operation plan has been performed for a predetermined period is calculated by integrating the state change amounts of the battery in the plurality of time frames from the time point of starting the operation to the time point when a predetermined period has passed. The processing circuit 21 calculates the capacity retention rate of the battery capacity, the resistance increase rate of the resistance, and the like as indices indicating the degradation state of the battery based on a calculation result of the state change amount at the time point when the predetermined period has passed since the time point of starting the operation.

In the processing of the example of FIG. 2, when calculating the degradation state of the battery of the case where the battery is operated in accordance with the operation plan, the processing circuit 21 of the processing apparatus 20 transmits notification information including the calculation result of the degradation state of the battery to the processing apparatus 10 via the communication module 23 (S106). Then, the processing circuit 11 of the processing apparatus 10 receives the notification information from the processing apparatus 20 via the communication module 13 (S107). Then, the processing circuit 11 causes the user interface 15 or the like to notify the notification information received from the processing apparatus 20 (S108). As a result, the user or the like of the information processing system 1 is notified of the degradation state of the battery of the case where the battery is operated in accordance with the operation plan. The notification of the notification information is performed by, for example, any of screen display, transmission of sound, or the like.

As described above, in the present embodiment, the time-series data indicating the time change in each of the current, the voltage, and the temperature of the battery of the case where the battery is operated in accordance with the operation plan in the operation plan information is calculated based on the operation plan information indicating the operation plan of either the battery or a battery-mounted apparatus in which the battery is mounted. Then, the degradation state of the battery of the case where the battery is operated in accordance with the operation plan is calculated using the calculated time-series data. Thereby, it is possible to estimate the degradation state of the battery of the case where the battery is operated in accordance with the operation plan at a stage before the battery is operated, such as a stage of the operation plan. For example, at the stage before the battery is operated, it is possible to estimate the degradation state of the battery at the time point when the operation of the battery in accordance with the operation plan has been performed for a predetermined period.

In addition, in the present embodiment, the calculation result of the degradation state of the battery of the case where the battery is operated in accordance with the operation plan is notified. As a result, the user or the like who performs the operation plan can recognize the degradation state of the battery of the case where the battery is operated in accordance with the operation plan before the operation. Therefore, the user or the like can determine whether or not the planned operation plan is appropriate, whether or not change of the operation plan is necessary, and the like at the stage before the operation.

Further, in the present embodiment, in the calculation of the degradation state of the battery, the time range indicated by the time-series data is divided into a plurality of time frames, and one or more operation condition parameters each indicating the operation condition of the battery are calculated for each of the plurality of divided time frames based on the time-series data. Then, for each of the plurality of time frames, the state change amount of the battery is calculated based on the calculated operation condition parameters, and the degradation state of the battery of the case where the battery is operated in accordance with the operation plan is calculated based on the calculation result of the state change amount of the battery in each of the plurality of time frames. Therefore, the degradation state of the battery of the case where the battery is operated in accordance with the operation plan is appropriately calculated using the calculated time-series data.

### Second Embodiment

Next, a second embodiment will be described as a modification of the first embodiment. In the present embodiment, an operation condition calculation program is stored in a storage medium 22 of a processing apparatus (second processing apparatus) 20 in addition to a data management program 25 and a degradation state calculation program 26. The operation condition calculation program constitutes a part of an information processing program.

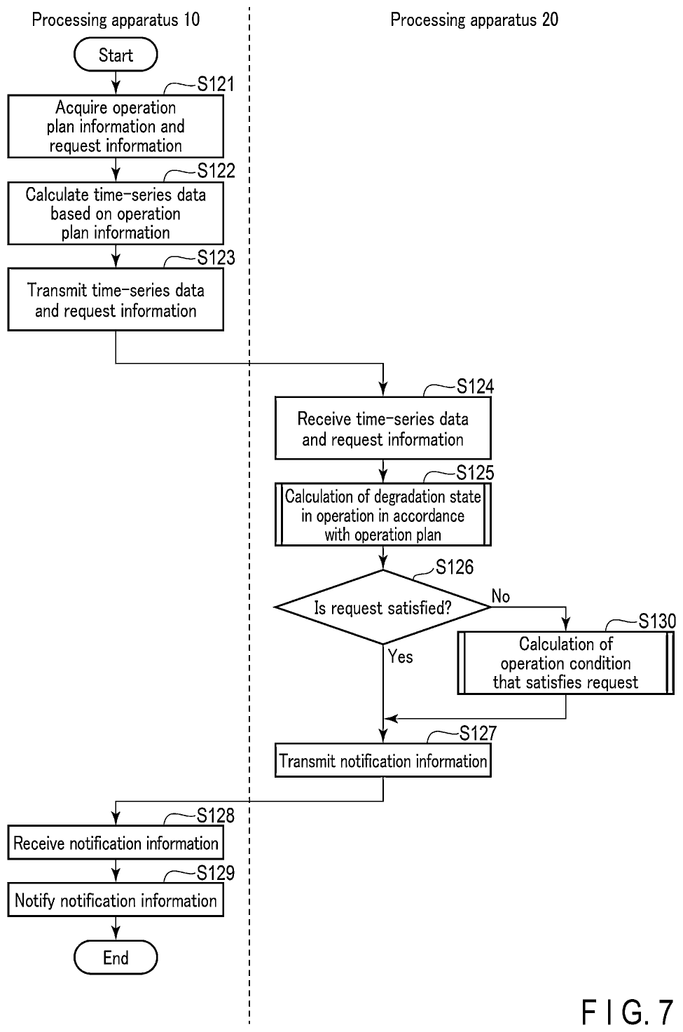

FIG. 7 is a flowchart schematically illustrating an example of processing performed by an information processing system 1 according to the second embodiment. The processing of the example of FIG. 7 is mainly performed by a processing circuit 11 of a processing apparatus 10 and a processing circuit 21 of the processing apparatus 20, and is performed by the processing apparatuses 10 and 20 or the like executing the information processing program including a time-series data calculation program 17, the degradation state calculation program 26, and the operation condition calculation program.

In the present embodiment, when the processing of the example of FIG. 7 is started, the processing circuit 11 of the processing apparatus 10 acquires request information indicating a user's request regarding a degradation state of a battery in addition to operation plan information (S121). The request information is input by the user or the like in a user interface 15. The request information indicates the request for the degradation state of the battery at a time point after a predetermined period has elapsed since a time point of starting an operation. In one example, the request information indicates a request at the time point after a predetermined period has elapsed since the time point of starting the operation for any one or more of a capacity retention rate of a battery capacity and a resistance increase rate of a resistance. For example, the request information indicates that the battery capacity retention rate is 80% or more and the resistance increase rate is twice or less at the time point when the 10000th charge of the battery has been performed since the time point of starting the operation.

In the present embodiment, the processing circuit 11 calculates time-series data based on the operation plan information using an electrochemical model Ma (S122). Therefore, also in the present embodiment, the time-series data indicating a time change in each of a current, a voltage, and a temperature of the battery of a case where the battery is operated in accordance with an operation plan in the operation plan information is calculated. The time-series data is calculated in a similar manner to that in the above-described embodiment or the like. In the present embodiment, the processing circuit 11 transmits the request information to the processing apparatus 20 in addition to the time-series data (S123). Then, the processing circuit 21 of the processing apparatus 20 receives the time-series data and the request information from the processing apparatus 10 (S124).

Also in the present embodiment, the processing circuit 21 calculates a degradation state of the battery of the case where the battery is operated in accordance with the operation plan in the operation plan information, using the time-series data received from the processing apparatus 10 (S125). The processing of calculating the degradation state of the battery in the operation in accordance with the operation plan is performed in a similar manner to the above-described embodiment or the like, and is performed in a similar manner to the processing of the example of FIG. 4, for example. In the present embodiment, the processing circuit 21 compares a calculation result of the degradation state of the battery with respect to the user's request indicated by the request information. Then, the processing circuit 21 determines whether or not the calculation result of the degradation state of the battery in the operation in accordance with the operation plan satisfies the user's request (S126). At this time, for example, it is determined whether or not any one of the capacity retention rate of the battery capacity or the resistance increase rate of the resistance at the time point when the operation in accordance with the operation plan has been performed for a predetermined period satisfies the request indicated by the request information.

In a case where the calculation result of the degradation state of the battery satisfies the user's request (S126—Yes), the processing circuit 21 of the processing apparatus 20 transmits notification information including the calculation result of the degradation state of the battery to the processing apparatus 10 as in the above-described embodiment or the like (S127). Then, the processing circuit 11 of the processing apparatus 10 receives the notification information from the processing apparatus 20 (S128), and causes the user interface 15 or the like to notify the notification information received from the processing apparatus 20 (S129).

In a case where the calculation result of the degradation state of the battery does not satisfy the user's request (S126—No), the processing circuit 21 calculates an operation condition of the battery that satisfies the user's request (S130). The processing circuit 21 calculates the operation condition of the battery that satisfies the user's request by executing the operation condition calculation program. Then, the processing circuit 21 adds the calculation result regarding the operation condition of the battery that satisfies the user's request in the notification information in addition to the calculation result regarding the degradation state of the battery, and transmits the notification information to the processing apparatus 10 (S127).

Then, the processing circuit 11 receives the notification information from the processing apparatus 20 (S128), and causes the user interface 15 or the like to notify the notification information (S129). Since such processing is performed, in the case where the calculation result of the degradation state of the battery does not satisfy the user's request, the calculation result of the operation condition of the battery that satisfies the user's request is notified to the user or the like of the information processing system 1 in addition to the degradation state of the battery of the case where the battery is operated in accordance with the operation plan.

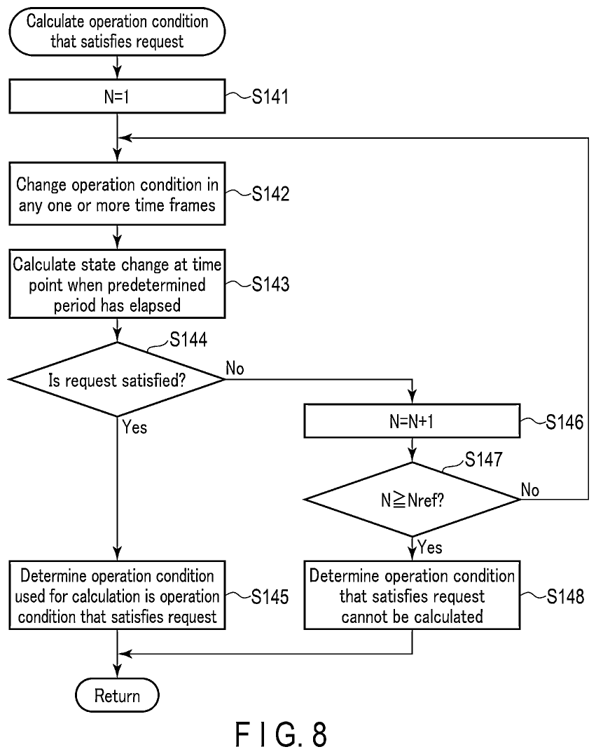

FIG. 8 is a flowchart schematically illustrating an example of the processing of calculating the operation condition of the battery that satisfies the user's request, that is, the processing of S130 of FIG. 7, which is performed in the second embodiment. In the processing of the example of FIG. 8, the number of changes N is defined as the number of times an operation condition parameter has been changed. When the processing of the example of FIG. 8 is started, the processing circuit 21 sets the number of changes N to 1 (S141).

Then, the processing circuit 21 changes the operation condition in any one or more of a plurality of time frames obtained by dividing a time range indicated by the time-series data (S142). At this time, in each of the time frames in which the operation condition is changed, one or more values of the operation parameters are changed. As a result, the operation condition is changed from a calculation result based on the time-series data in any one or more of the plurality of time frames. Then, in each of the time frames in which the operation condition is changed, any one or more of the operation condition parameters are changed from calculated values based on the time-series data.

Then, the processing circuit 21 changes the operation condition in the one or more time frames, and calculates the degradation state of the battery at the time point when a predetermined period has elapsed since the time point of starting the operation (S143). At this time, the degradation state of the battery is calculated using a degradation prediction model Mb, similarly to the calculation of the degradation state of the battery of the case where the battery is operated in accordance with the operation plan. Therefore, by performing similar processing to the processing of S113 to S115 of the example of FIG. 4, the degradation state of the battery at the time point when a predetermined period has elapsed since the time point of starting the operation is calculated. That is, the processing circuit 21 calculates a state change speed and a state change amount of the battery for each of the plurality of time frames based on the operation condition parameters. Then, the processing circuit 21 calculates a state change of the battery at the time point when a predetermined period has elapsed since the time point of starting the operation as the degradation state of the battery based on a calculation result of the state change amount of the battery in each of the plurality of time frames.

Here, similarly to the example of FIG. 5, it is assumed that the operation condition parameter has been calculated based on the time-series data, and the degradation state of the battery in the operation in accordance with the operation plan has been calculated using the operation condition parameter, for each of the plurality of time frames. Then, it is assumed that the calculation result of the degradation state of the battery does not satisfy the user's request. In this case, for example, in each of time frames Ya, the processing circuit 21 changes a maximum SOC value and a minimum SOC value from the calculated values based on the time-series data, and calculates the degradation state of the battery at the time point when a predetermined period has elapsed since the time point of starting the operation. In one example, in each of the time frames Ya, the maximum SOC value is changed from an SOC value η1 based on the time-series data to an SOC value η3 lower than the SOC value η1, and the minimum SOC value is changed from an SOC value η2 based on the time-series data to an SOC value η4 lower than the SOC value η2.

In the processing of the example of FIG. 8, when calculating the degradation state of the battery at the time point when the predetermined period has elapsed, the processing circuit 21 compares a calculation result of the degradation state of the battery with respect to the user's request indicated by the request information. Then, the processing circuit 21 determines whether or not the calculation result of the degradation state of the battery in the arithmetic operation in which the operation condition has been changed in any one or more of the time frames satisfies the user's request (S144).

In a case where the calculation result of the degradation state of the battery satisfies the user's request (S144—Yes), the processing circuit 21 determines that the operation condition used to calculate the degradation state of the battery is the operation condition that satisfies the user's request (S145). At this time, for each of the plurality of time frames, the operation condition parameter used to calculate the degradation state of the battery is calculated as the operation condition of the battery that satisfies the user's request. Further, in the notification information, the operation condition used to calculate the degradation state of the battery is indicated as the calculation result of the operation condition of the battery that satisfies the user's request, and for example, the operation condition parameter used to calculate the degradation state of the battery is indicated for each of the plurality of time frames.

Here, similarly to the above-described example, it is assumed that the maximum SOC value is changed from the SOC value η1 to the SOC value η3, the minimum SOC value is changed from the SOC value η2 to the SOC value η4, and the degradation state of the battery at the time point when a predetermined period has elapsed since the time point of starting the operation is calculated, in each of the time frames Ya. Then, it is assumed that the calculation result of the degradation state of the battery in the arithmetic operation in which the value of the operation condition parameter has been changed satisfies the user's request. In this case, the notification information indicates, as the calculation result of the operation condition of the battery that satisfies the user's request, the operation condition of the battery that satisfies the user's request, and that the operation condition has been changed from the operation in accordance with the operation plan of the operation plan information as described above.

Further, in a case where the calculation result of the degradation state of the battery does not satisfy the user's request (S144—No), the processing circuit 21 adds one to the number of changes N (S146). Then, the processing circuit 21 determines whether or not the counted number of changes N is greater than or equal to a reference number of times Nref (S147). In a case where the number of changes N is smaller than the reference number of times Nref (S147—No), the processing returns to S142, and the processing circuit 21 sequentially performs the processing of S142 and the subsequent steps.

For this reason, in a case where the number of changes N does not reach the reference number of times Nref, the operation condition is changed from the previous calculation of the degradation state in any one or more of the plurality of time frames, and the arithmetic operation is performed for the degradation state of the battery at the time point when a predetermined period has elapsed since the time point of starting the operation. Then, the processing of S142 to S144 is repeatedly performed until the number of changes N reaches the reference number of times Nref or until the operation condition of the battery that satisfies the user's request is calculated.

In one example, in the processing of S142, the operation condition is changed in consideration of a history of the change in the operation condition up to the previous calculation of the degradation state. For example, in the previous calculation of the degradation state, it is assumed that an SOC value of the minimum SOC value, which is one of the operation condition parameters, is increased in one or more time frames as compared with the one before last calculation of the degradation state. Then, it is assumed that a difference from the user's request is smaller in the calculation result in the previous calculation of the degradation state than the calculation result in the one before last calculation of the degradation state. In this case, for example, in each of the time frames in which the SOC value of the minimum SOC value has been changed in the previous calculation of the degradation state, the minimum SOC value is changed to the SOC value higher than the previous calculation of the degradation state.

Further, in the previous calculation of the degradation state, it is assumed that the SOC value of the minimum SOC value, which is one of the operation condition parameters, is decreased in one or more time frames as compared with the one before last calculation of the degradation state. Then, it is assumed that a difference from the user's request is larger in the calculation result in the previous calculation of the degradation state than the calculation result in the one before last calculation of the degradation state. In this case, for example, in each of the time frames in which the SOC value of the minimum SOC value has been changed in the previous calculation of the degradation state, the minimum SOC value is changed to the SOC value higher than the one before last calculation of the degradation state.

In a case where the number of changes N is equal to or larger than the reference number of times Nref (S147—Yes), the processing circuit 21 determines that the operation condition that satisfies the user's request cannot be calculated (S148). In this case, the notification information indicates that the operation condition that satisfies the user's request has not been calculated as the calculation result of the operation condition of the battery that satisfies the user's request.

The present embodiment also has similar functions and effects to those of the first embodiment and the like. Therefore, in the present embodiment, it is also possible to estimate the degradation state of the battery of the case where the battery is operated in accordance with the operation plan at a stage before the battery is operated, such as a stage of the operation plan.

In addition, in the present embodiment, the calculation result of the degradation state of the battery of the case where the battery is operated in accordance with the operation plan is compared with the user's request. Then, in the case where the calculation result of the degradation state does not satisfy the user's request, the operation condition of the battery that satisfies the user's request is calculated by changing the operation condition from the calculation result based on the time-series data in any one or more of the plurality of time frames and performing the arithmetic operation of the degradation state of the battery. Therefore, in the case where the request is not satisfied by the operation in accordance with the operation plan, the user or the like can modify the operation plan based on the calculation result of the operation condition of the battery that satisfies the user's request.

### Third Embodiment

Next, a third embodiment will be described as a modification of the first embodiment. In the present embodiment, a type selection program is stored in a storage medium 22 of a processing apparatus (second processing apparatus) 20 in addition to a data management program 25 and a degradation state calculation program 26. The type selection program constitutes a part of an information processing program.

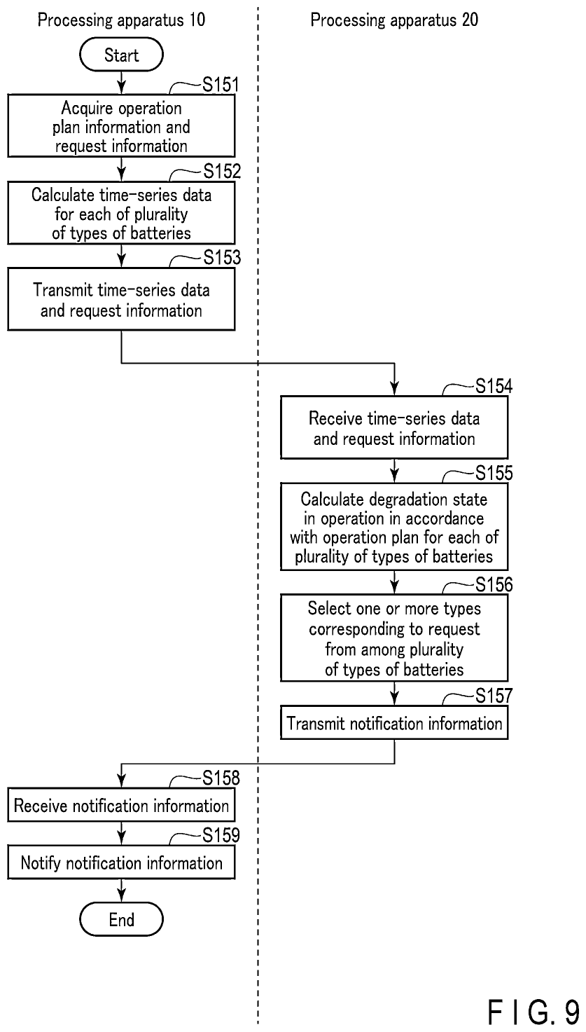

FIG. 9 is a flowchart schematically illustrating an example of processing performed by an information processing system 1 according to the third embodiment. The processing of the example of FIG. 9 is mainly performed by a processing circuit 11 of a processing apparatus 10 and a processing circuit 21 of the processing apparatus 20, and is performed by the processing apparatuses 10 and 20 or the like executing the information processing program including a time-series data calculation program 17, the degradation state calculation program 26, and the type selection program.

In the present embodiment, when the processing of the example of FIG. 9 is started, the processing circuit 11 of the processing apparatus 10 acquires operation plan information and request information indicating a user's request as in the second embodiment and the like (S151). In addition, in an example of the present embodiment, a type of a battery to be operated is indicated in addition to the above-described information in the operation plan information. As described above, each of a plurality of types of batteries is different from the other types of batteries in any one or more of a composition of a positive electrode, a composition of a negative electrode, and a composition of an electrolyte. Therefore, in the batteries of different types from one another, a voltage range, a battery capacity, and the like used in operation are different from one another.

In the present embodiment, the processing circuit 11 calculates time-series data based on the operation plan information for each of the plurality of types of batteries different from one another (S152). Therefore, for each of the plurality of types of batteries, the time-series data indicating a time change in each of a current, a voltage, and a temperature of the battery of a case where the battery is operated in accordance with an operation plan in the operation plan information is calculated. Here, in the case where the type of the battery to be operated is indicated in the operation plan information, the plurality of types of batteries for which the time-series data is calculated includes the same type as the battery to be operated in the operation plan information.

In the present embodiment, the same number of electrochemical models Ma as the number of types of batteries for which the time-series data is calculated are stored in a storage medium 12, and one corresponding electrochemical model Ma is used for each type of battery. In a case where the time-series data is calculated for each of the plurality of types of batteries, the processing circuit 11 inputs the operation plan information to each of the plurality of electrochemical models Ma, and causes the each of the plurality of electrochemical models Ma to output the time-series data. The calculation of the time-series data is performed in a similar manner to the above-described embodiment or the like except that the time-series data is calculated for each of the plurality of types of batteries.

In one example, three electrochemical models Ma1, Ma2, and Ma3 are stored in the storage medium 12 corresponding to three types of batteries β1, β2, and β3. Then, the time-series data of the battery of the type β1 is calculated by inputting the operation plan information to the electrochemical model Ma1, the time-series data of the battery of the type β2 is calculated by inputting the operation plan information to the electrochemical model Ma2, and the time-series data of the battery of the type β3 is calculated by inputting the operation plan information to the electrochemical model Ma3.

In the present embodiment, the processing circuit 11 transmits the time-series data of each of the plurality of types of batteries and the above-described request information to the processing apparatus 20 (S153). Then, the processing circuit 21 of the processing apparatus 20 receives the time-series data of each of the plurality of types of batteries and the request information from the processing apparatus 10 (S154).

In the present embodiment, the processing circuit 21 calculates, for each of the plurality of types of batteries, a degradation state of the battery of the case where the battery is operated in accordance with the operation plan in the operation plan information using the time-series data received from the processing apparatus 10 (S155). Therefore, for each of the plurality of types of batteries, the degradation state of the battery at the time point when the operation in accordance with the operation plan has been performed for a predetermined period is calculated. Here, in the case where the type of the battery to be operated is indicated in the operation plan information, the plurality of types of batteries for which the degradation state in the operation in accordance with the operation plan is calculated includes the same type as the battery to be operated in the operation plan information.

In the present embodiment, the same number of degradation prediction models Mb as the number of types of batteries for which the time-series data is calculated are stored in the storage medium 22 or the like, and one corresponding degradation prediction model Mb is used for each type of battery. Further, in the present embodiment, as described above, the same number of pieces of time-series data as the number of the electrochemical models Ma are calculated. Therefore, in a case of calculating the degradation state in the operation in accordance with the operation plan for each of the plurality of types of batteries, the processing circuit 21 inputs a corresponding one of the plurality of pieces of time-series data to each of the plurality of degradation prediction models Mb. Then, the processing circuit 21 causes each of the plurality of degradation prediction models Mb to output the degradation state of the battery of the case where the battery is operated in accordance with the operation plan.

The calculation of the degradation state of the battery in the operation in accordance with the operation plan is performed in a similar manner to the above-described embodiment or the like except that the degradation state is calculated for each of the plurality of types of batteries. For example, the degradation state of the battery of the case where the battery is operated in accordance with the operation plan is calculated by performing processing similar to the processing of the example of FIG. 4 for each of the plurality of types of batteries.

In one example, three degradation prediction models Mb1, Mb2, and Mb3 are stored in the storage medium 22, and time-series data is calculated for each of the three types β1, β2, and β3 of batteries. Then, the degradation state of the battery of the type β1 in the operation in accordance with the operation plan is calculated by inputting the time-series data for the battery of the type β1 to the degradation prediction model Mb1, the degradation state of the battery of the type β2 in the operation in accordance with the operation plan is calculated by inputting the time-series data for the battery of the type 2 to the degradation prediction model Mb2, and the degradation state of the battery of the type β3 in the operation in accordance with the operation plan is calculated by inputting the time-series data for the battery of the type B3 to the degradation prediction model Mb3.

In the present embodiment, the processing circuit 21 compares a calculation result of the degradation state of each of the plurality of types of batteries with respect to the user's request indicated by the request information. Then, the processing circuit 21 selects one or more types suitable for operation from among the plurality of types of batteries corresponding to the user's request (S156). At this time, in a case where the calculation result of the degradation state of the battery in the operation in accordance with the operation plan satisfies the user's request in one or more types of batteries among the plurality of types of batteries, one or more types of batteries in which the calculation result of the degradation state satisfies the user's request are selected as the batteries suitable for the operation.

For example, it is assumed that the request information indicates that a battery capacity retention rate is 80% or more and a resistance increase rate is twice or less at the time point when a predetermined period has elapsed since the time point of starting the operation. Then, it is assumed that the degradation state of the battery at the time point when the predetermined period has elapsed since the time point of starting the operation is calculated for the three types β1 to β3 of batteries. Then, in the calculation results of the degradation states, it is assumed that the battery capacity retention rate was 78% and the resistance increase rate was 2.3 times in the battery of the type β1, the battery capacity retention rate was 85% and the resistance increase rate was 1.9 times in the battery of the type β2, and the battery capacity retention rate was 78% and the resistance increase rate was 1.8 times in the battery of the type β3. In this case, the battery of the type 2 is selected as the type suitable for the operation, corresponding to the request of the user.

Furthermore, in the processing of S156, a situation in which the calculation result of the degradation state of the battery in the operation in accordance with the operation plan satisfies the user's request may occur in the two or more types of batteries. In this case, in one example, all types of batteries in which the calculation result of the degradation state satisfies the user's request are selected as the batteries suitable for the operation. In another example, one type having the lowest degree of degradation in the calculated degradation state is selected as the battery suitable for the operation from among all the types of batteries in which the calculation result of the degradation state satisfies the user's request.

For example, it is assumed that the request information indicates that the battery capacity retention rate is 80% or more and the resistance increase rate is twice or less at the time point when a predetermined period has elapsed since the time point of starting the operation. Then, it is assumed that at least the degradation state of the battery at the time point when a predetermined period has elapsed since the time point of starting the operation is calculated for the types β1 and β2 of batteries. In the calculation results of the degradation states, it is assumed that the battery capacity retention rate was 80% and the resistance increase rate was 2 times in the battery of the type β1, and the battery capacity retention rate was 85% and the resistance increase rate was 1.9 times in the battery of the type β2. In this case, in one example, both of the two types β1 and β2 of batteries are selected as the batteries suitable for the operation. In another example, the battery of the type β2 having the lowest degree of degradation in the calculated degradation state is selected as the battery suitable for the operation from among the two types β1 and β2 of batteries in which the calculation result of the degradation state satisfies the user's request.

Furthermore, in the processing of S156, a situation in which the calculation result of the degradation state of the battery in the operation in accordance with the operation plan does not satisfy the user's request may occur in any type of battery. In this case, one type having a smallest difference in the calculation result of the degradation state with respect to the user's request is selected from among the plurality of types of batteries as the battery suitable for the operation.

For example, it is assumed that the request information indicates that the battery capacity retention rate is 80% or more and the resistance increase rate is twice or less at the time point when a predetermined period has elapsed since the time point of starting the operation. Then, it is assumed that the degradation state of the battery at the time point when the predetermined period has elapsed since the time point of starting the operation is calculated for the three types β1 to β3 of batteries. Then, in the calculation results of the degradation states, it is assumed that the battery capacity retention rate was 78% and the resistance increase rate was 2.3 times in the battery of the type β1, the battery capacity retention rate was 79% and the resistance increase rate was 1.8 times in the battery of the type β2, and the battery capacity retention rate was 75% and the resistance increase rate was 1.8 times in the battery of the type β3. In this case, the battery of the type β2 having the smallest difference in the calculation result of the degradation state with respect to the user's request is selected from among the plurality of types of batteries as the battery suitable for the operation.

In the processing of the example of FIG. 9, when selecting one or more types of batteries suitable for the operation, the processing circuit 21 transmits notification information to the processing apparatus 10 (S157). In the present embodiment, the calculation result regarding the degradation state of each of the plurality of types of batteries of the case where the battery is operated in accordance with the operation plan, and a selection result of the one or more types selected from among the plurality of types of batteries, corresponding to the request of the user, are included in the notification information.

Then, the processing circuit 11 receives the notification information from the processing apparatus 20 (S158), and causes the user interface 15 or the like to notify the notification information (S159). Since such processing is performed, the calculation result regarding the degradation state of each of the plurality of types of batteries of the case where the battery is operated in accordance with the operation plan, and the selection result of the one or more types selected from among the plurality of types of batteries, corresponding to the request of the user, are notified to the user of the information processing system 1 or the like.

The present embodiment also has similar functions and effects to those of the first embodiment and the like. Therefore, in the present embodiment, it is also possible to estimate the degradation state of the battery of the case where the battery is operated in accordance with the operation plan at a stage before the battery is operated, such as a stage of the operation plan.

Therefore, in the present embodiment, for each of the plurality of types of batteries, the time-series data indicating the time change in each of the current, the voltage, and the temperature of the case where the battery is operated in accordance with the operation plan is calculated. Then, for each of the plurality of types of battery, the degradation state of the case where the battery is operated in accordance with the operation plan is calculated using the calculated time-series data. Thereby, it is possible to estimate the degradation state of the battery of the case where the battery is operated in accordance with the operation plan at a stage before the battery is operated, such as a stage of the operation plan, for each of the plurality of types of batteries different from one another.

Further, in the present embodiment, one or more types suitable for the operation are selected from among the plurality of types of batteries, corresponding to the request of the user, by comparing the calculation result of the degradation state of each of the plurality of types of batteries with respect to the user's request. Therefore, the user or the like can check which type is suitable for the operation in accordance with the operation plan among the plurality of types of batteries whose degradation states are estimated. Further, in the case where the type of the battery to be operated at the stage of the operation plan is present, the user or the like can confirm whether or not the type of the battery to be operated is appropriate.

### Modification

Note that, in a modification, both processing similar to that of the second embodiment or the like and processing similar to that of the third embodiment or the like are performed. In the present modification, similarly to the third embodiment or the like, the time-series data is calculated for each of the plurality of types of batteries, and the degradation state of the case where the battery is operated in accordance with the operation plan is calculated using the calculated time-series data for each of the plurality of types of batteries. Then, in any type of battery, in a case where the calculation result of the degradation state of the battery in the operation in accordance with the operation plan does not satisfy the user's request, the operation condition of the battery that satisfies the user's request is calculated in a similar manner to that in the second embodiment or the like. At this time, for example, the operation condition of the battery that satisfies the user's request is calculated for one type having the smallest difference in the calculation result of the degradation state with respect to the user's request.

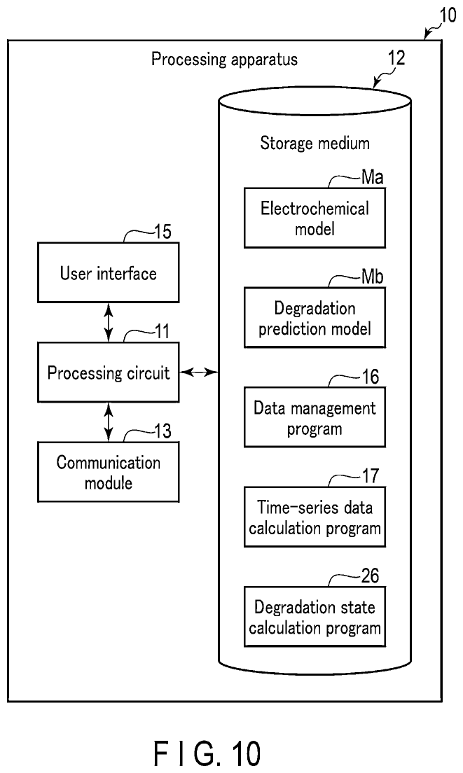

FIG. 10 is a block diagram schematically illustrating the information processing system 1 according to a modification. As illustrated in FIG. 10, also in the present modification, the processing apparatus 10 includes the processing circuit 11, the storage medium (non-transitory storage medium) 12, the communication module 13, and the user interface 15. However, in the present modification, the degradation state calculation program 26 and the degradation prediction model Mb are stored in the storage medium 12 in addition to the data management program 16, the time-series data calculation program 17, and the electrochemical model Ma. In one example of the present modification, the processing circuit 11 of the processing apparatus 10 downloads the degradation state calculation program 26 and the degradation prediction model Mb in addition to the time-series data calculation program 17 and the electrochemical model Ma by downloading a dedicated application via the network, and stores the downloaded time-series data calculation program 17, degradation state calculation program 26, electrochemical model Ma, and degradation prediction model Mb in the storage medium 12.

Also in the present modification, the processing circuit 11 of the processing apparatus 10 calculates, based on the operation plan information indicating the operation plan of either the battery or a battery-mounted apparatus in which the battery is mounted, the time-series data indicating the time change in each of the current, the voltage, and the temperature of the battery of the case where the battery is operated in accordance with the operation plan in the operation plan information. Note that, in the present modification, the processing circuit 11 calculates the degradation state of the battery of the case where the battery is operated in accordance with the operation plan using the calculated time-series data. At this time, similarly to the processing by the processing circuit 21 of the processing apparatus 20 in the above-described embodiment or the like, the degradation state of the battery in the operation in accordance with the operation plan is calculated. Further, also in the present modification, the processing circuit 11 notifies the calculation result of the degradation state of the battery of the case where the battery is operated in accordance with the operation plan via the user interface 15 or the like.

Note that, in a modification, the processing circuit 11 of the processing apparatus 10 performs processing similar to the processing performed by the processing circuit 21 of the processing apparatus 20 in the second embodiment or the like. In this case, the processing circuit 11 downloads the degradation state calculation program 26, the operation condition calculation program, and the degradation prediction model Mb together with the time-series data calculation program 17 and the electrochemical model Ma by downloading a dedicated application. Furthermore, in a modification, the processing circuit 11 of the processing apparatus 10 performs processing similar to the processing performed by the processing circuit 21 of the processing apparatus 20 in the third embodiment or the like. In this case, the processing circuit 11 downloads the degradation state calculation program 26, the type selection program, and the degradation prediction model Mb together with the time-series data calculation program 17 and the electrochemical model Ma by downloading a dedicated application.

In the at least one embodiment or example described above, the time-series data indicating the time change in each of the current, the voltage, and the temperature of the battery of the case where the battery is operated in accordance with the operation plan in the operation plan information is calculated based on the operation plan information indicating the operation plan of either the battery or a battery-mounted apparatus in which the battery is mounted. Then, the degradation state of the battery of the case where the battery is operated in accordance with the operation plan is calculated using the calculated time-series data. Accordingly, it is possible to provide an information processing method, an information processing system, and an information processing program for a battery, which enable estimation of a degradation state of the battery of the case where the battery is operated in accordance with the operation plan before the battery is operated.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An information processing method for a battery, comprising:
calculating, based on operation plan information indicating an operation plan of either the battery or a battery-mounted apparatus in which the battery is mounted, time-series data indicating each time change in a current, a voltage, and a temperature of the battery of a case where the battery is operated in accordance with the operation plan in the operation plan information; and
calculating a degradation state of the battery of the case where the battery is operated in accordance with the operation plan, using the calculated time-series data.

2. The information processing method according to claim 1, comprising:
in the calculating a degradation state of the battery,
dividing a time range indicated by the time-series data into a plurality of time frames and calculating one or more operation condition parameters each indicating an operation condition of the battery for each of the divided time frames based on the time-series data;
calculating a state change amount of the battery for each of the time frames based on the calculated operation condition parameters; and
calculating the degradation state of the battery of the case where the battery is operated in accordance with the operation plan based on a calculation result of the state change amount of the battery in each of the time frames.

3. The information processing method according to claim 2, comprising:
in the calculating the degradation state of the battery,
calculating, as the operation condition parameters, a maximum SOC value of the battery, a minimum SOC value of the battery, an average temperature of the battery, and an average current value of the battery for each of the time frames included in a time domain in which either charging or discharging of the battery is performed among the time frames based on the time-series data; and
calculating, as the operation condition parameters, a maintained SOC value of the battery and the average temperature of the battery for each of the time frames included in a time domain in which charging and discharging of the battery are stopped among the time frames based on the time-series data.

4. The information processing method according to claim 2, further comprising:
comparing a calculation result of the degradation state of the battery with a request of a user, and
in a case where the calculation result of the degradation state does not satisfy the request of the user, calculating the operation condition of the battery that satisfies the request of the user by changing the operation condition from a calculation result based on the time-series data in any one or more of the time frames and performing an arithmetic operation for the degradation state of the battery.

5. The information processing method according to claim 4, further comprising:
in a case where the calculation result of the degradation state does not satisfy the request of the user, notifying the calculation result of the degradation state of the battery of the case where the battery is operated in accordance with the operation plan and a calculation result of the operation condition of the battery that satisfies the request of the user.

6. The information processing method according to claim 1, comprising:
in the calculating time-series data, calculating, for each of a plurality of types of batteries different from one another, time-series data indicating each time change in the current, the voltage, and the temperature of the case where the battery is operated in accordance with the operation plan, and
in the calculating a degradation state of the battery, calculating a degradation state of the case where the battery is operated in accordance with the operation plan, using the calculated time-series data, for each of the plurality of types of batteries.

7. The information processing method according to claim 6, further comprising:
selecting one or more types suitable for operation from among the plurality of types of batteries, corresponding to a request of a user, by comparing a calculation result of the degradation state of each of the plurality of types of batteries with respect to the request of the user.

8. The information processing method according to claim 7, further comprising:
notifying the calculation result regarding the degradation state of each of the plurality of types of batteries of the case where the battery is operated in accordance with the operation plan, and a selection result of the one or more types selected from among the plurality of types of batteries, corresponding to the request of the user.

9. The information processing method according to claim 1, further comprising:
notifying a calculation result of the degradation state of the battery of the case where the battery is operated in accordance with the operation plan.

10. An information processing system for a battery, comprising:
a processing circuit that
calculates, based on operation plan information indicating an operation plan of either the battery or a battery-mounted apparatus in which the battery is mounted, time-series data indicating each time change in a current, a voltage, and a temperature of the battery of a case where the battery is operated in accordance with the operation plan in the operation plan information; and
calculates a degradation state of the battery of the case where the battery is operated in accordance with the operation plan, using the calculated time-series data.

11. The information processing system according to claim 10, further comprising:
a processing apparatus in which the processing circuit is mounted, wherein
the processing circuit of the processing apparatus calculates the time-series data and calculates the degradation state of the battery.

12. The information processing system according to claim 10, further comprising:
a first processing apparatus in which a first processing circuit is mounted as the processing circuit; and
a second processing apparatus in which a second processing circuit different from the first processing circuit is mounted as the processing circuit, wherein
the first processing circuit of the first processing apparatus calculates the time-series data and transmits the calculated time-series data from the first processing apparatus to the second processing apparatus, and the second processing circuit of the second processing apparatus calculates the degradation state of the battery and transmits a calculation result of the degradation state of the battery from the second processing apparatus to the first processing apparatus.

13. A non-transitory storage medium storing an information processing program for a battery causing a computer to implement:
calculating, based on operation plan information indicating an operation plan of either the battery or a battery-mounted apparatus in which the battery is mounted, time-series data indicating each time change in a current, a voltage, and a temperature of the battery of a case where the battery is operated in accordance with the operation plan in the operation plan information; and
calculating a degradation state of the battery of the case where the battery is operated in accordance with the operation plan, using the calculated time-series data.
